(19) United States
(12) Patent Application Publication
(10) Pub. No.: US 2015/0345053 A1
(43) Pub. Date: Dec. 3, 2015

(54) COMPOSITE ROPE AND MESH NET MADE THEREFROM

(71) Applicant: Niles Mittet SKARBÖVIG, (US)

(72) Inventors: Nils Mittet SKARBOVIG, Vredenburg (ZA); Michael Gordon DICKSON, Bergendal (ZA)

(21) Appl. No.: 14/410,276

(22) PCT Filed: Jun. 19, 2013
(86) PCT No.: PCT/IB2013/055024

§ 371 Date: Dec. 22, 2014

(30) Foreign Application Priority Data
Jun. 27, 2012 (ZA) 2012/04784
Sep. 11, 2012 (ZA) 2012/06772

(51) Int. Cl. D04C 1/06; E21D 11/00; G01R 31/02; A01K 3/00; F41H 11/12; E02D 17/20; E04H 17/04

(52) U.S. Cl. CPC D04C 1/06; E02D 17/202; E21D 11/003; E21D 11/006; E04H 17/04; A01K 3/005; F41H 11/12; G01R 31/025

(57) ABSTRACT

The invention provides a composite rope (10, 20) and mesh net (50) made therefrom. The composite rope (10, 20) comprises a plurality of outer fibre strands (14, 24) twisted or braided around an inner elongate core (12, 22) so as to provide the rope (10, 20) with increased durability. The inner elongate core (12, 22) extends at least partially in a helical configuration, and may comprise an expanded metal wire core having a helical configuration, alternatively a number of steel or synthetic elongate strands or filaments (26) wound to form a twisted cable in which each strand or filament (26) has a helical configuration. The mesh net (50) comprises a number of lengths of rope (52) knotted together at regular spaced intervals, with the net (50) being stretched and heat set during manufacture, and wherein the mesh net (50) includes at least some lengths of composite rope (10, 20) in accordance with the invention. The invention further provides for methods of using the mesh net (50).

### FIELD OF THE INVENTION

This invention relates to a composite rope and a mesh net made therefrom.

### BACKGROUND TO THE INVENTION

Nets made from knotted synthetic ropes are used in various ways ranging from safety nets used in mines to catch falling pieces of rock to nets used to secure cargo in place during transportation by ship, airplane or vehicle. Although these nets are lightweight and cost effective, they may not be sufficiently strong or durable for certain applications and are generally easily cut.

### SUMMARY OF THE INVENTION

In accordance with this invention there is provided a composite rope comprising a plurality of outer fibre strands twisted or braided around an inner elongate core, wherein at least a portion of the inner elongate core extends in a helical configuration, the inner elongate core providing the rope with increased durability.

In one embodiment of the invention, the elongate core is an expanded metal wire core which has a helical configuration; the metal wire core is made from spring steel; and the metal wire core is a tightly wound helix with adjacent coils of the helix close together or touching each other when the metal wire core is not under tension.

In a different embodiment of the invention, the elongate core is formed from a number of elongate strands or filaments wound to form a twisted cable in which each filament has a helical configuration. The elongate strands or filaments may be made from steel in which case the elongate core is a wound steel cable, alternatively the elongate strands may be made from synthetic material such as aramid fibres (for example, carbon fibre) in which case the elongate core is a synthetic cable.

Further features of the invention provide for the outer fibre strands to be synthetic fibre strands such as high-density polyethylene (HDPE), nylon, polyester or polypropylene.

The invention extends to a mesh net comprising a number of lengths of rope knotted together at regular spaced intervals to form the mesh net, wherein at least some of the lengths of rope are of composite rope that includes a plurality of outer fibre strands twisted or braided around an inner elongate core, at least a portion of the inner elongate core extending in a helical configuration, the composite rope providing the mesh net with increased durability.

Still further features of the invention provide for the mesh net to be made from alternating lengths of composite rope and non-composite rope.

Yet further features of the invention provide for the mesh net to be stretched and heat set during its manufacture, so that knots of the mesh net are both tightened and the fibre strands bonded to prevent the knots from loosening.

The invention extends to a method of safeguarding goods during their transportation, comprising securing about the goods a mesh net according to the invention.

Further features of the invention provide for the mesh net to be secured about goods transported on a ground transportation vehicle; and for the ground transportation vehicle to include a curtain-sided truck or trailer or a flatbed truck or trailer.

Still further features of the invention provide for the mesh net to be secured adjacent to at least one tarpaulin curtain of a curtain-sided truck or trailer; for the mesh net to be suspended from anchor points on the truck or trailer; and for the mesh net to be secured on the inside of the tarpaulin curtain so that it is not visible from outside of the truck or trailer.

Still further features of the invention provide for the mesh net to be secured in an orientation so that the lengths of rope extend at approximately 45 degrees to the horizontal, so that a cutting instrument which is inserted into the mesh net and pulled either down or horizontally abuts against one of the knots.

Yet further features of the invention provide for the mesh net to be secured only partway up the height of the tarpaulin curtain; for the mesh net to be secured adjacent to at least the tarpaulin curtain of the ground transportation vehicle closest to the road edge in use; and for the mesh net to be loosely fastened so that a cutting instrument causes the net to bunch together.

Still further features of the invention provide for the method to include passing an electrical current through the inner elongate core of the composite rope of the mesh net; and detecting cutting of the composite rope in the event that the electrical current passed through the inner elongate core is short-circuited.

The invention extends to a method of stabilizing earth works or excavations, comprising securing adjacent the earth works or excavations a mesh net according to the invention.

The invention extends to a method of controlling lateral expansion of a geotextile grout bag used in underground mining operations, the method comprising securing about the grout bag a mesh net according to the invention.

The invention extends to a method of preventing damage or injury in an underground mining operation, the method comprising suspending a mesh net according to the invention adjacent a hanging wall or roof of an underground mine shaft so as to catch broken pieces of rock.

The invention extends to a method of safely detonating anti-personnel land mines comprising passing an electrical current through composite rope of a mesh net according to the invention and dragging the mesh net across a land surface under which a land mine is buried, the electrostatic or electromagnetic charge carried on the mesh net causing the land mine to detonate.

The invention extends to a fencing or barrier system for controlling access to an area or premises, the fencing or barrier system including one or more mesh nets according to the invention which optionally are electrically charged.

### BRIEF DESCRIPTION OF THE DRAWINGS

The invention will now be described, by way of example only with reference to the accompanying representations in which:

FIG. 1 is a partial cut-away side view of a first embodiment of a composite rope according to the invention;

FIG. 2 is a three dimensional view of the composite rope of FIG. 1;

FIG. 3 is a partial cut-away side view of a second embodiment of a composite rope according to the invention;

FIG. 4 is a three dimensional view of the composite rope of FIG. 3;

FIG. 5 is a front view of a mesh net according to the invention;

FIG. 6 illustrates the mesh net of FIG. 5 in a suspended condition;

FIG. 7 is a close up view of a portion of the suspended mesh net of FIG. 6;

FIG. 8 illustrates a person cutting through a tarpaulin curtain of a ground transportation vehicle from the outside; and,

FIG. 9 is the same as FIG. 8 but shown from the inside of the transportation vehicle.

### DETAILED DESCRIPTION WITH REFERENCE TO THE DRAWINGS

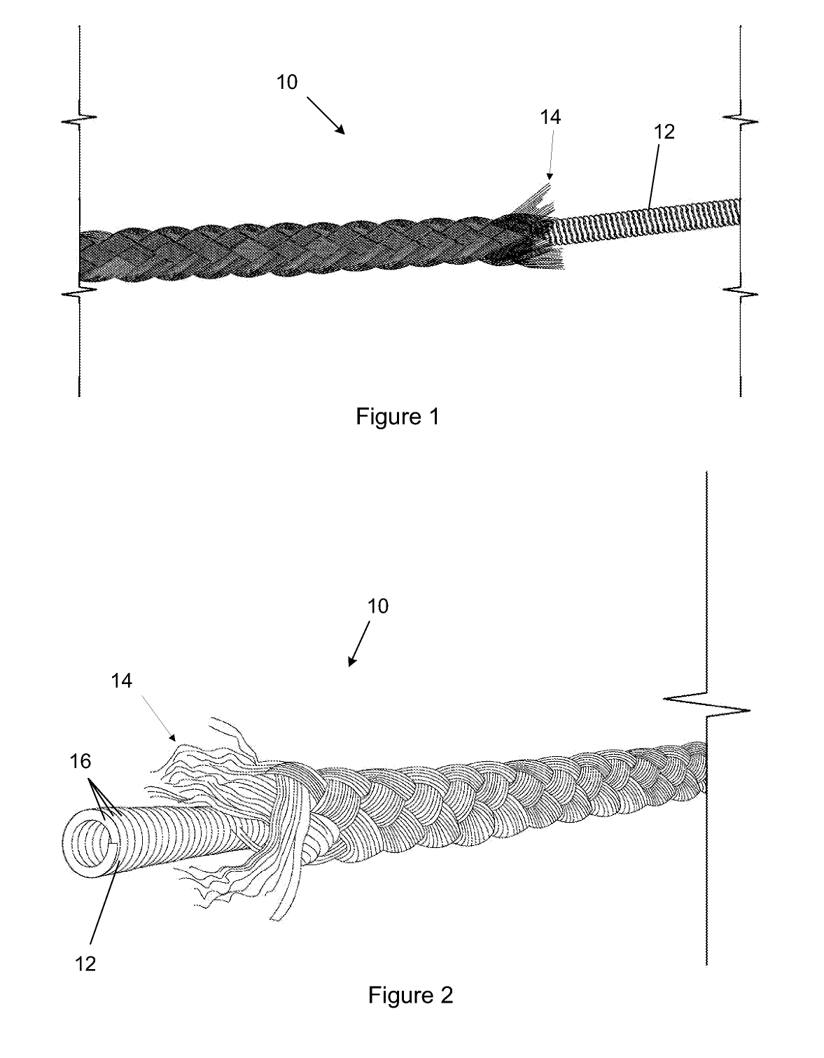

FIG. 1 shows a composite rope (10) according to a first embodiment of the invention. The composite rope includes an inner elongate core (12) surrounded by a plurality of outer fibre strands (14), which are shown in partial cut-away so that the inner elongate core is visible. The fibre strands may be twisted or braided around the core, and may be made from synthetic fibre strands such as high-density polyethylene (HDPE), nylon, polyester or polypropylene. In the illustrated embodiment, the fibre strands are braided HDPE strands.

The inner elongate core (12) is an expanded metal wire core which has a helical configuration shown most clearly in FIG. 2. The metal wire core is made from spring steel and is a tightly wound helix with adjacent coils (16) of the helix close together or even touching each other when the metal wire core is not under tension. The metal wire core provides the rope with increased durability as explained further below.

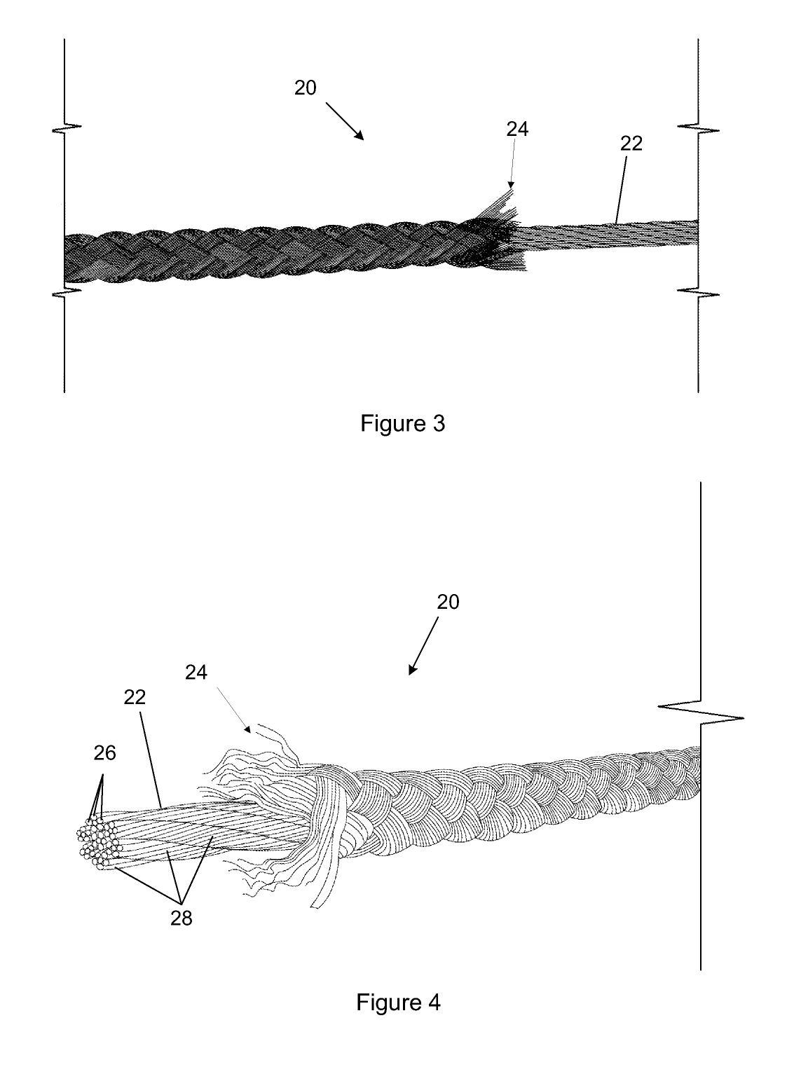

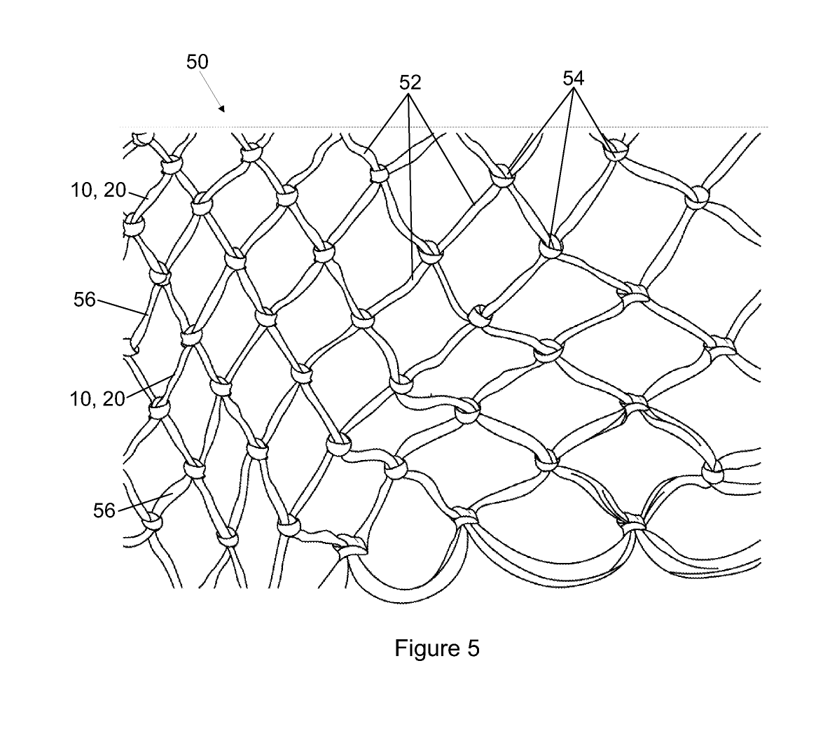

FIGS. 3 and 4 show a composite rope (20) according to a second embodiment of the invention. Similar to the embodiment of FIGS. 1 and 2, the composite rope (20) also includes an inner elongate core (22) surrounded by braided HDPE strands (24), but in the embodiment of FIGS. 3 and 4 the inner elongate core (22) is formed from a number of elongate strands or filaments (26) wound to form a twisted cable in which each filament extends in a helical configuration. The elongate strands or filaments may be made from steel in which case the elongate core is a wound steel cable, alternatively the elongate strands may be made from synthetic material such as aramid fibres (for example, carbon fibre) in which case the elongate core is a synthetic cable. In the illustrated embodiment of FIGS. 3 and 4, the elongate core is a wound steel cable in which several groups (28) of steel filaments are twisted first around each other and then twisted together as adjacent groups. The wound steel cable may optionally be surrounded by a plastic coating (not shown), which helps to prevent the filaments from unravelling. The wound steel cable provides the rope with increased durability as explained further below.

FIG. 5 illustrates a mesh net (50) comprising a number of lengths of rope (52) knotted together at regular spaced intervals to form a mesh net with a number of knots (54). At least some of the lengths of rope are composite rope (10) as illustrated in FIGS. 1-2 or composite rope (20) as illustrated in FIGS. 3-4.

While the mesh net of FIG. 5 could be constructed entirely from composite rope (10 or 20), thereby providing maximum strength and durability, in the illustrated embodiment the mesh net (50) is made from alternating lengths of composite rope (10 or 20) and ordinary synthetic rope (56). This arrangement saves on cost and makes the mesh net significantly lighter without greatly compromising its ability to be breached, as will be explained below. In this arrangement, for every knot (54) that has only synthetic rope in the knot, its adjacent knots have either one or two composite ropes in their knots.

During manufacture of the mesh net of FIG. 5, the mesh net (50) is stretched and heat set. The process of stretching and heat setting ensures that the knots (54) of the mesh net are both tightened and the fibre strands (14 or 24) bonded to prevent the knots from loosening. Because the inner elongate core of the composite rope has a helical configuration (either as a helical metal wire core (12) or a twisted steel cable (22)), it is able to stretch and flex at the knot and not break or weaken as may be the case with a solid wire core.

The mesh of the mesh net (50) preferably has a dimension of 50-100 by 50-100 millimetres, and more preferably of 75 by 75 millimetres. The relatively small dimension of the mesh will increase the difficulty of breaching the net (50) and removing goods that are being held within the net as is further described below.

The mesh net of the invention can be used in a variety of applications and as part of a variety of systems. One application of the mesh net of the invention is in the protection of goods transported on a ground transportation vehicle such as a curtain-sided truck or trailer or a flatbed truck or trailer. During the overland transportation of cargo, goods may be susceptible to theft. Vehicles for the overland transportation of valuable cargo commonly provide for a tarpaulin curtain or cover to block the goods from view and to provide some form of protection against theft. The tarpaulin curtain or cover is, however, generally made from plastics material and consequently does not provide effective resistance to cutting instruments such as knives. Thieves can gain access to the goods by slashing open the tarpaulin curtain or cover with a knife or other cutting instrument.

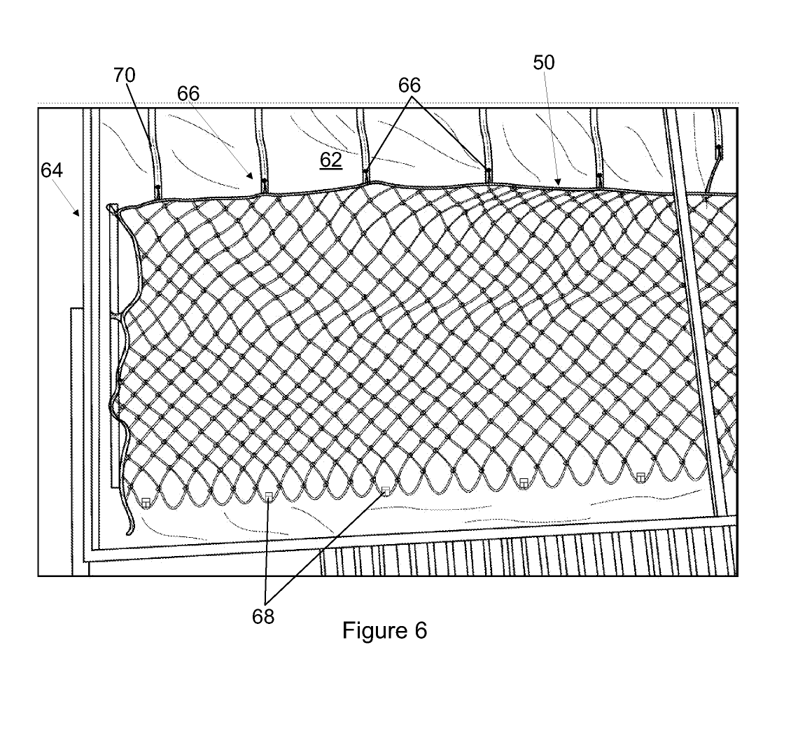

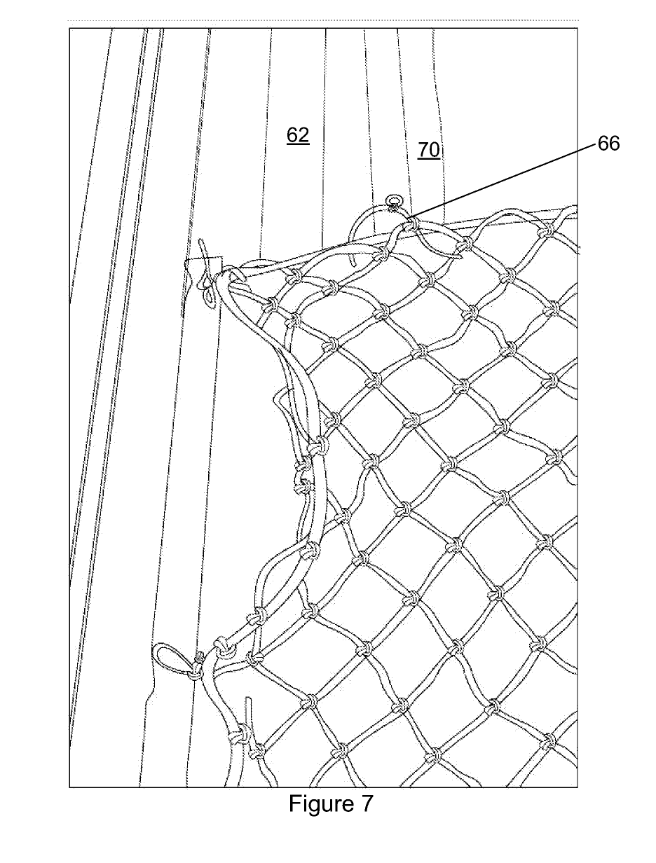

FIGS. 6 and 7 show one application in which the mesh net of the invention can be used to secure goods during their transportation in a curtain-sided trailer. In the embodiment illustrated in FIG. 6, the mesh net (50) is secured adjacent to a tarpaulin curtain (62) of a curtain-sided trailer (64) in which goods (not shown) are transported. The mesh net is secured on an inside of the tarpaulin curtain (62) so that the mesh net is not visible from the outside of the trailer, and is secured by suspending the mesh net from anchor points (66) on the trailer and securing the net to ties (68) on a floor of the trailer. One anchor point (66) is shown in more detail in FIG. 7. The anchor point (66) is connected to a webbing strap (70) which can be used in conjunction with a ratchet (not shown) to suspend the net.

The mesh net (50) is preferably secured in an orientation so that, as shown in FIGS. 6 and 7, the lengths of rope extend at approximately 45 degrees to the horizontal. The mesh net is preferably fitted to the inside of the tarpaulin curtain while the tarpaulin is laid flat on a floor of its manufacturing facility.

In a preferred embodiment, the mesh net (50) is secured only partway up the height of the tarpaulin curtain (62) of the ground transportation vehicle. The mesh net should preferably be secured to cover a height of about 1.5 metres upwards from the bottom of the cargo area. In addition the mesh net is preferably secured adjacent to at least the tarpaulin curtain (62) of the ground transportation vehicle closest to the road edge (not shown) in use. The applicant believes that breaches in the tarpaulin curtain almost always occur in the lower 1.5 metre section thereof, and also mostly on the road edge side of the vehicle. Fitting the nets on the road edge side and up to about 1.5 metres may therefore provide sufficient protection of the goods being transported, while reducing the cost of covering the entire surface of the tarpaulin curtain. The mesh net is also preferably loosely fastened rather than being held taut which, in addition to making it harder to breach as will be described below, allows the net to bunch together more easily when the curtain tarpaulin is drawn to one side.

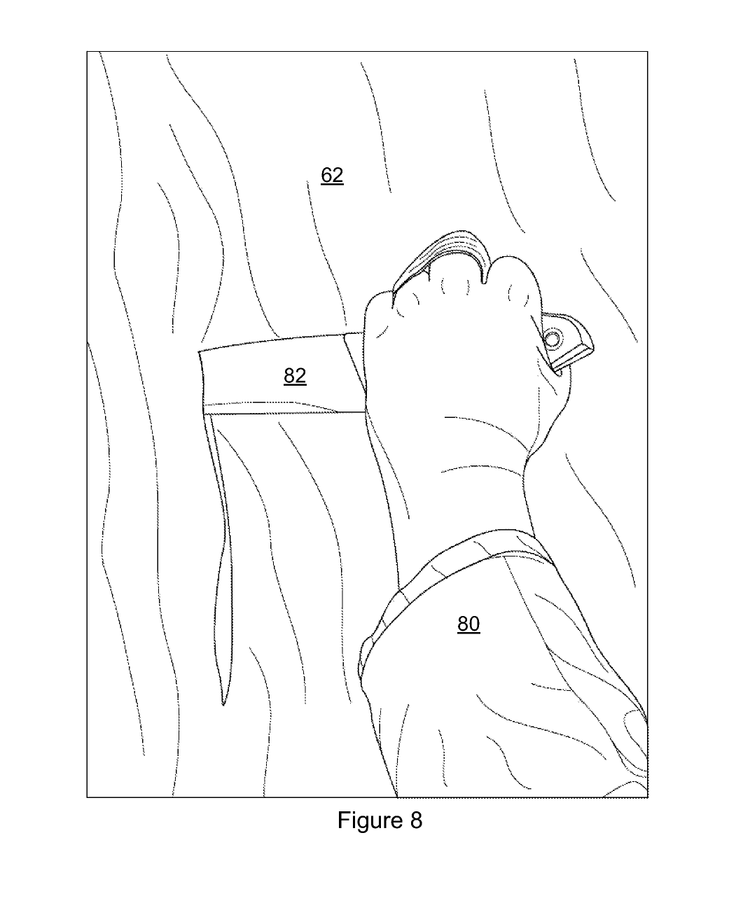

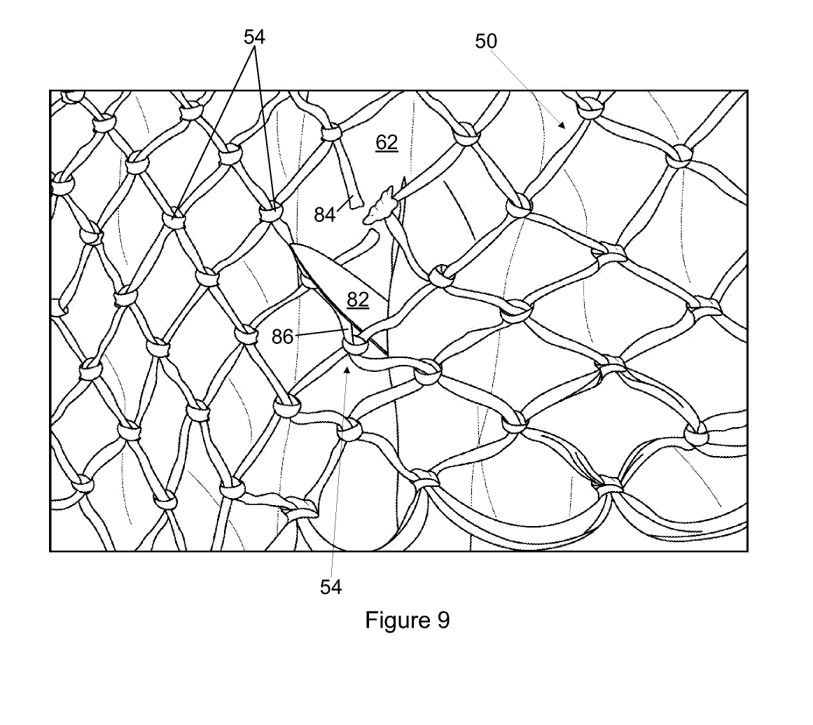

FIG. 8 shows a person (80) cutting through the tarpaulin curtain (62) of a curtain-sided ground transportation vehicle from the outside using a knife (82). As tarpaulin curtains are typically made from plastics materials (such as PVC coated plastics), the knife can easily pierce and slice the curtain.

FIG. 9 is the same as FIG. 8 but shows the tarpaulin curtain (62) from the inside of the cargo area of the ground transportation vehicle. As shown in FIG. 9, a mesh net (50) according to the invention has been fitted adjacent the tarpaulin curtain. The knife (82) is shown as having pierced the tarpaulin curtain and the person is attempting to cut through the mesh net (50). Because the mesh net (50) is made from alternating lengths of composite rope and ordinary synthetic rope, as previously described, the person was able to cut through one of the ropes (84), which is a section of rope that only includes ordinary synthetic rope. However, the adjacent rope (86) of the mesh net is a composite rope of the invention. The composite rope (86) with its inner elongate core has prevented the knife from further cutting into the mesh net (50) and thereby prevented the person from gaining access to the cargo transported by the ground transportation vehicle.

The securing of the mesh net in an orientation so that the lengths of rope extend at approximately 45 degrees to the horizontal also ensures that when pulling the knife either vertically or horizontally, the knife will abut against one of the knots (54). This will increase the difficulty of cutting through the net, as the rope is thickest at the knot. Furthermore, because the net is loosely fastened, a knife will cause the net to bunch together, making it harder to sever the ropes of the net. The bunching of the mesh net will also ensure that when a knife or other cutting instrument is removed and then re-inserted, the probability of the knife cutting at the same rope or location on the rope of the net is reduced, further increasing the difficulty of cutting through the net.

The applicant has found the mesh net of the invention to be difficult to cut with all kinds of knives, scissors and saws. The mesh net was even found to be difficult to breach with a chain saw, as a chain saw snags on the composite rope and bounces back at its user.

The composite rope and mesh net of the invention can also have an electrical current passed through the conductive metal wire core of embodiments of the composite rope. This electric current may be sufficient to provide an electric shock to a person attempting to breach it, thereby providing a further deterrent, or may be a trickle current which allows a sensing circuit to detect cutting of the composite rope if the current is short-circuited. Such a sensing circuit could be coupled to an alarm which could notify the driver of a breach or attempted breach of the mesh net, and could optionally report the breach of the mesh net to a central point such as a control centre. Communication with the control centre could be by radio, cellular telephone or satellite communication and the control centre could be an emergency response centre which dispatches armed security personnel to the location of the transportation vehicle.

While FIGS. 6 to 9 illustrate one application in which the mesh net of the invention can be used to secure goods during their transportation in a curtain-sided trailer, the composite rope as well as nets made therefrom may be used for various other purposes. In one aspect of the invention, which is not illustrated, the mesh net of the invention is used for stabilizing earth works or excavations by securing the mesh net against the earth works or excavations. Embodiments that fall within this aspect include using the mesh net of the invention to replace wirework containers filled with rock or other material called gabions or reno mattresses, or to replace geo grids or very heavy grade woven fabrics which are currently used to prevent slips on earth cuts and fills. The mesh net of the invention is lighter, cheaper to produce and more versatile than these existing systems while being sufficiently strong and durable for certain applications.

In a still further aspect of the invention, which is not illustrated, the mesh net of the invention is secured about a geotextile grout bag used in underground mining operations, to control lateral expansion of the geotextile grout bag as occurs during axial load thereof. Such a grout pack system is lighter and easier to handle and install than previous systems which generally use steel restraining rings or bars.

In a yet further aspect of the invention, which is not illustrated, the mesh net of the invention is suspended adjacent a hanging wall or roof of an underground mining operation so as to catch broken pieces of rock and help prevent injury and damage to property. The mesh net of the invention is more durable than previously used knotted nets made from synthetic rope only.

In a further aspect of the invention, which is not illustrated, the mesh net of the invention is used to safely detonate anti-personnel land mines by passing an electrical current through the composite rope of the mesh net and dragging the mesh net across a land surface under which a land mine is buried. The resultant electrostatic or electromagnetic charge carried on the mesh net causes the land mine to detonate and the mesh net helps to prevent extensive damage.

Other applications for the mesh net and/or composite rope of the invention are for perimeter safety fencing purposes including military applications or electrified wild game perimeter nets, catch nets, cover safety nets, electrified anti-ship boarding nets, riot or crowd control shock nets, cargo hoisting or sling nets, any of which may be electrified and linked electronically to alarm systems, warning systems or electric shock systems. Yet further applications include thermal netting for agriculture or even below surface thermal netting to replace existing below surface blankets.

1. A mesh net comprising a number of lengths of rope knotted together at regular spaced intervals to form the mesh net, wherein at least some of the lengths of rope are of a composite rope that includes a plurality of outer fibre strands twisted or braided around an inner elongate core, the inner elongate core providing the composite rope with increased durability.

2. A mesh net as claimed in claim 1, wherein the elongate core is an expanded metal wire core which has a helical configuration.

3. A mesh net as claimed in claim 2, wherein the metal wire core is made from spring steel and is a tightly wound helix with adjacent coils of the helix close together or touching each other when the metal wire core is not under tension.

4. A mesh net as claimed in claim 1, wherein the elongate core is formed from a number of elongate strands or filaments wound to form a twisted cable in which each filament has a helical configuration.

5. A mesh net as claimed in claim 4, wherein the elongate core is a wound steel cable in which the elongate strands or filaments are made from steel.

6. A mesh net as claimed in claim 4, wherein the elongate core is a synthetic cable in which the elongate strands or filaments are made from synthetic material.

7. A mesh net as claimed in claim 1, wherein the outer fibre strands are synthetic fibre strands selected from high-density polyethylene (HDPE), nylon, polyester and polypropylene.

8. (canceled)

9. A mesh net as claimed in claim 1, wherein the mesh net is made from alternating lengths of composite rope and non-composite rope.

10. A mesh net as claimed in claim 1, wherein the mesh net is stretched and heat set during its manufacture, so that knots of the mesh net are both tightened and the fibre strands bonded to prevent the knots from loosening.

11. A method of safeguarding goods during their transportation, the method comprising securing about the goods a mesh net as claimed in claim 1.

12. A method of safeguarding goods as claimed in claim 11, wherein the mesh net is secured about the goods transported on a ground transportation vehicle, and the vehicle is a curtain-sided truck or trailer or a flatbed truck or trailer.

13. A method of safeguarding goods as claimed in claim 12, wherein the mesh net is secured by suspending the mesh net from anchor points on the inside of and adjacent to at least one tarpaulin curtain of a curtain-sided truck or trailer so that the mesh net is not visible from outside of the truck or trailer.

14. A method of safeguarding goods as claimed in claim 13, wherein the mesh net is secured in an orientation so that the lengths of rope extend at approximately 45 degrees to the horizontal, so that a cutting instrument which is inserted into the mesh net and pulled either down or horizontally abuts against a knot.

15. A method of safeguarding goods as claimed in claim 13 wherein the mesh net is secured only partway up the height of at least the tarpaulin curtain of the ground transportation vehicle closest to the road edge in use, and wherein the mesh net is loosely secured adjacent the tarpaulin curtain so that a cutting instrument causes the net to bunch together.

16. A method of safeguarding goods as claimed in claim 11, wherein the method includes passing an electrical current through the inner elongate core of the composite rope of the mesh net, and detecting cutting of the composite rope in the event that the electrical current passed through the inner elongate core is short-circuited.

17. A method of stabilizing earth works or excavations, comprising securing adjacent the earth works or excavations a mesh net as claimed in claim 1.

18. A method of controlling lateral expansion of a geotextile grout bag used in underground mining operations, the method comprising securing about the grout bag a mesh net as claimed in claim 1.

19. A method of preventing damage or injury in an underground mining operation, the method comprising suspending a mesh net as claimed in claim 1 adjacent a hanging wall or roof of an underground mine shaft so as to catch broken pieces of rock.

20. A method of safely detonating anti-personnel land mines comprising passing an electrical current through the composite rope of a mesh net as claimed in claim 1 and dragging the mesh net across a land surface under which a land mine is buried, the electrostatic or electromagnetic charge carried on the mesh net causing the land mine to detonate.

21. A fencing or barrier system for controlling access to an area or premises, the fencing or barrier system including one or more mesh nets as claimed in claim 1 and wherein the mesh net or nets are optionally electrically charged.

22. A mesh net as claimed in claim 1, wherein at least a portion of the inner elongate core extends in a helical configuration.
